(19) United States
(12) Patent Application Publication
(10) Pub. No.: US 2009/0019795 A1
(43) Pub. Date: Jan. 22, 2009

(54) Roof Cover or Facade Siding

(76) Inventors: Tamas Szacsvay, Azmoos (CH); Patrick Hofer-Noser, Thun (CH)

Correspondence Address: COLLARD & ROE, P.C., 1077 NORTHERN BOULEVARD, ROSLYN, NY, 11576, US

(21) Appl. No.: 11/885,008

(22) PCT Filed: Feb. 24, 2006
(86) PCT No.: PCT/EP2006/001711

§ 371 Date: Sep. 4, 2008

(30) Foreign Application Priority Data
Feb. 24, 2005 (EP) 05003971.8

(51) Int. Cl. E04D 1/12; E04D 12/00; E04D 1/34; E04D 13/18; H01L 31/048; E04D 1/20; E04F 13/08

(52) U.S. Cl. 52/173.3; 52/546; 52/551; 126/622; 136/251

(57) ABSTRACT

The roof or facade cladding comprises panel-shaped construction elements (1) arranged in a scale-type pattern, and each construction element (1) comprises at least a panel part (2), a frame and at least one retaining element (6). Each construction element (1) is secured by the at least one retaining element (6) on an essentially horizontally disposed support element (27). Each retaining element (6) is disposed on the respective construction element (1) adjacent to a bottom, essentially horizontally oriented edge (5) of the construction element (1) and the point (20) of the retaining element (6) contacting the support element (27) lies closer to this bottom edge (5) than the top edge (11) of the construction element (1). Each construction element is protected from mechanical damage all the way round at the edges the frame. The retaining elements (6) primarily secure the bottom edge of the construction element (1), whilst the top part of the construction elements and their frames lie underneath the construction element disposed in the next row above and is fixed thereby.

The invention relates to a roof or facade cladding of panel-shaped construction elements disposed in a scale type pattern, and every construction element has at least one retaining element which is disposed on the internal face of the construction element facing the building, and every construction element is secured by the at least one retaining element disposed on an essentially horizontally disposed support element due to a downwardly open slot provided in the retaining element which extends round the support element in a clamping arrangement, and the at least one retaining element is disposed on the construction element adjacent to the bottom, essentially horizontally oriented edge of the construction element and the slot of the retaining element extending round the support element lies closer to this bottom edge than the top front face of the construction element.

In order to secure them to roof battens, known construction elements, e.g. roof tiles, have downwardly extending lugs on the top edge. Grooves and webs are provided at the sides, which form a labyrinth seal with the adjacent left-hand and right-hand elements to prevent penetration by rain or melting water. If roofs or facades are to be clad with flat, panel-shaped elements instead of tiles, they must overlap with one another in the horizontal direction (e.g. in an offset, shingled pattern) or must be provided with a device to provide a seal in the horizontal direction, and are attached by means of hooks or retaining brackets secured to the sub-structure for example, which extend round the bottom edge of the construction element, thereby providing a fixing on the building. It is also necessary to provide means for producing a seal in the vertical direction.

In this respect, international patent application WO 00/02256 A1 discloses a method whereby aluminium extruded sections are used, which are attached to all edges of a preferably rectangular, panel shaped component, and the component contains photovoltaic elements. These form a seal with the adjacent components at the right-hand and left-hand edge and are sealed in the vertical direction due to an overlap, and the components are each secured at the bottom edge by means of hooks screwed into roof battens. The disadvantages of this method are, for example, the fact that hooks have to be individually screwed into the battens before laying the components and the electrical circuitry for the photovoltaic elements has to be fitted on the internal face directed towards the building. For aesthetic reasons, an aluminium frame is also often felt to be a disadvantage.

Patent applications JP 2003-276 042 A and JP 11-068 136 A mention solar modules with a glass pane totally surrounded by a frame of injection moulded plastic, the main focus being on the actual injection moulding technique and the seal of the edge of the solar modules, as well as the fitting of the solar modules framed in this manner in a complex type of construction comprising posts and bolts with various special parts. Accordingly, the objective of providing a simple connecting means to the building remains unsolved and the resultant solar modules are also not suitable for providing a seal between the individual solar modules by means of their intrinsic structure. Injecting round a glass pane by an injection moulding process constitutes prior art, in particular in the field of car windows, and is therefore not the subject matter of this patent application.

Yet other solutions for securing panel-shaped construction elements such as solar modules are known, for example from patent application DE 199 21 044 A1, where a support structure is used which can be directly connected to standard roof tiles by means of rabbeted joints and an overlap. The width of this support structure usually corresponds to that of several roof tiles. The panel-shaped construction elements are secured to this support structure and this support structure is in turn secured to a roof batten by means of its external face. Although this is an elegant solution, it does have a disadvantage insofar as a different type of support structure has to be produced for every type of roof tile. Furthermore, these construction elements have to be screwed into the battens in order to ensure that they are sufficiently well secured to meet the relevant standards.

Patent application EP 1 362 967 A1 discloses panel-shaped construction elements overlapping in a scale-type pattern but these do not have a device integrated in the construction elements themselves for providing a seal between the individual construction elements in the horizontal direction. Retaining elements are not provided on the construction elements either, and instead, retaining elements are provided in the form of retaining brackets which are screwed into battens, which extend through the overlap region between the construction elements, and the construction element lying on top is secured by its bottom edge. The disadvantage of this is that prior to fitting the construction elements, profiled rails have to be laid in order to seal the construction elements in the horizontal direction and the retaining elements also have to be secured to the battens.

Publication DE 39 29 800 A1 relates to a device for securing a roof cladding panel. A fixing means is described, by means of which the relevant roof panels are particularly reliably held down and secured at the eaves end. The roof cladding panels have a fixing shoulder on their bottom face, which has a slot opening in the direction towards the eaves end. A flange attached to the roof construction extends through this slot. The downwardly projecting end region of the roof cladding panel overlaps with the next roof cladding panel and thus anchors it on the roof construction. Similar devices are disclosed in documents DE 37 13 320 A1 and FR 2 809 431 A1. These three systems all have a disadvantage in that the section bearing the flange has to be stepped so that the flange engaging in said slot sits farther away from the sub-structure than another flange lying opposite said flange by at least the thickness of the roof cladding panel, on which the next roof cladding panel lies by means of its top edge. Accordingly, the thickness of the roof cladding panels and the dimensions of the section must be adapted to one another. If the roof cladding panels contain photovoltaic elements, their electrical circuitry can not be disposed at the end face of the roof cladding panels lying at the top because this end face is covered by the section. Finally, due to the stepped design of the sections, it is difficult to make a lateral edge termination of the roof cladding, for example from sheet metal.

Against the background of this prior art, the objective of the invention is to propose a roof or facade cladding, which is protected against damage, is of a simple design, is extremely easy to fit and also does not require any specially stepped section.

This objective is achieved by the invention due to the fact that the construction element comprises at least a panel part and a frame at least partially surrounding the panel part, and the distance of the slot from the internal face of the construction element corresponds to at least the thickness of the construction element at its top end face.

Due to the frame, every construction element is protected against mechanical damage all the way round at the edges. Due to the position of the retaining elements in the bottom half of the construction element, it is primarily secured by its bottom edge. The top part of the construction element and its frame lie underneath the construction element in the next row above. Due to the overlap in the vertical direction, therefore, a seal is formed to prevent ingress by dust, dirt, snow, rain and melt water. At the same time, the construction element lying underneath is protected against wind suction by its top edge. Consequently, there is no need for retaining elements on the sub-structure, for example secured by mean of screws, which would have to be inserted through the overlap zone between the construction elements in order to secure the bottom edge of construction elements disposed in a scale pattern. In this area, this would either mean having to provide a significant gap between the construction elements or a special design enabling the retaining elements to be inserted at the relevant point. Sealing a gap or providing a special design means extra expense. The distance of the slot from the construction element enables the top edge of the adjacent construction elements underneath to sit on the same level as the support elements, where the slot also extends. Accordingly, there is no need to provide a specially stepped section, as is the case with the devices known from the prior art. This brings with it an additional advantage in that the top end face of the construction element is not covered by a wall of the section, as is the case with the known constructions, but remains accessible so that it can be used for fitting electric connection points if the construction element contains photovoltaic elements.

In one embodiment, the retaining element is disposed on the frame and is preferably integrally joined to the frame. This is conducive to transmitting force to the support element, in which case the panel element is not directly subjected to load.

If, as is the case with another embodiment, the frame is made from plastic and preferably is manufactured by an injection moulding process, it is easier produce large quantities inexpensively. The process of producing the construction elements can also be made easier if the panel part is joined to the frame by injecting round the panel part, as is the case in another embodiment.

In yet another embodiment, the support element is provided in the form of a profiled bar secured to the sub-structure, which has upwardly pointing legs spaced at a distance apart from the sub-structure. Due to the distance from the sub-structure, said leg is free along the entire length of the support element and the sub-structure and can thus be produced irrespective of the pattern formed by the construction elements.

In another embodiment, the bottom edge of the construction element is roughened on the face directed towards the support element and/or the top edge of the construction element facing away from the support element or is provided with ridges and/or ribs in the overlap region. This feature prevents any capillary action in the overlap region of the construction elements but nevertheless allows any condensation water which might have formed to drain away.

In another embodiment, the side edges of every construction element are provided with elements which engage in a sealing arrangement with co-operating elements of the horizontally adjacent construction elements. This prevents penetration by dust, dirt, snow, rain and melt water.

In another embodiment, the frame does not extend beyond the panel part at the bottom edge perpendicular to the plane of the panel part. Particularly in the case of a roof covering, this prevents dirt from accumulating at the bottom edge of the construction elements.

In another embodiment, the construction element contains a flat element made from inflammable material on its rear face. This element prevents parts from falling if the panel element breaks, which could occur if the building in question were on fire.

In a preferred embodiment of the invention, at least a part of the panel part is designed as a photovoltaic element or contains one. The frame advantageously protects the photovoltaic elements against mechanical stress and hence damage.

In another embodiment, the frame at the top edge of the construction element is so wide and the distance between the support elements is such that the bottom edge of the adjacent construction element above does not extend along the photovoltaic element or does so by a maximum of 5% of the vertical length of the photovoltaic element. This prevents losses of power production due to overshadowing by adjacent construction elements disposed above or reduces them to a minimum.

In one embodiment, at least one electric terminal is disposed in the top edge of the construction element, which is preferably accessible from the end face of the top edge. This allows a power circuit to be connected between already fitted construction elements at the top edge, instead of on the internal face of the construction element, which in the past has usually proved difficult to access.

In another embodiment, the photovoltaic elements are disposed on the internal face of the panel part and the frame is designed so that it forms the waterproof encapsulation of the photovoltaic elements, and the external face of the panel part is waterproof.

Specific embodiments of the invention will be described in more detail below with reference to examples illustrated in the appended drawings. Of these:

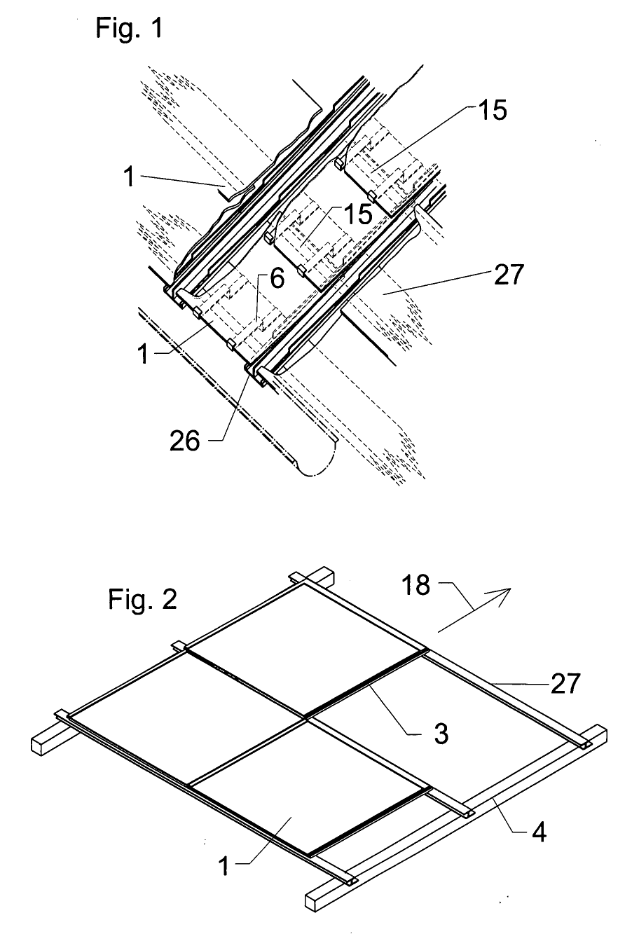

FIG. 1 illustrates a device known from the prior art with flat, panel-shaped construction elements;

FIG. 2 is a detail from a roof with fitted construction elements;

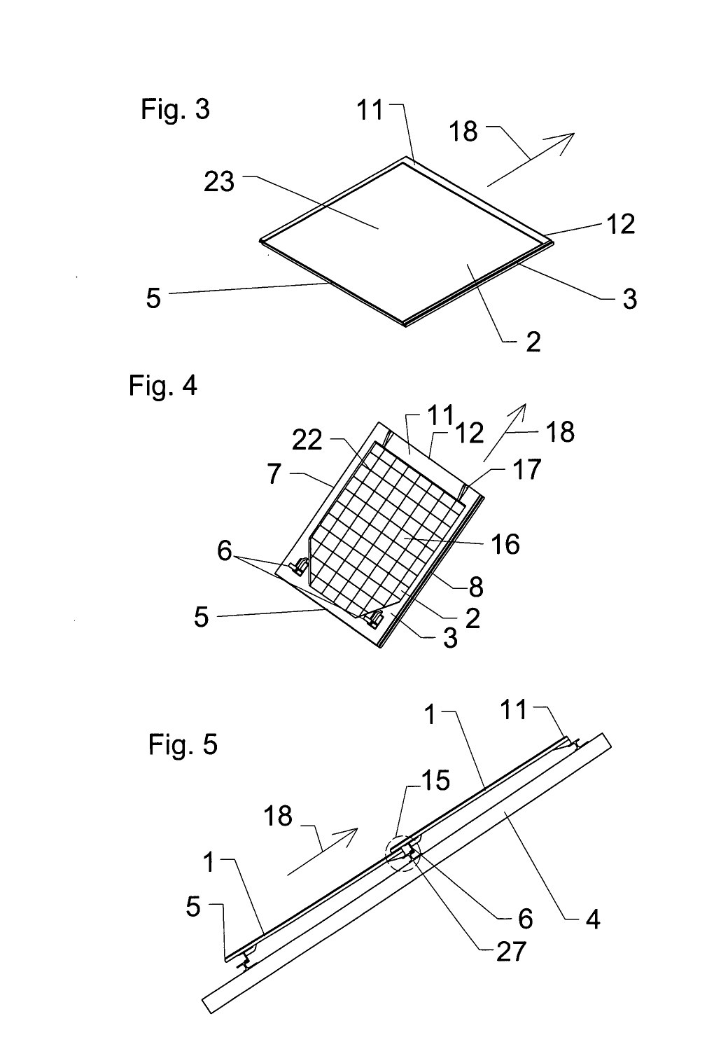

FIG. 3 is a view of the external face of the construction element;

FIG. 4 is a view of the internal face of the construction element;

FIG. 5 is a side view of fitted construction elements;

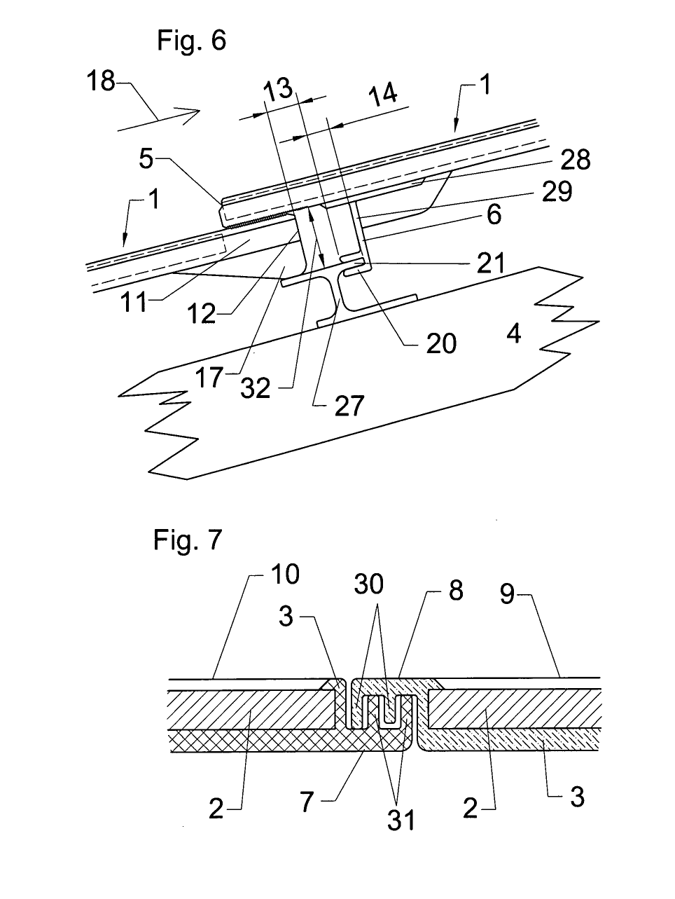

FIG. 6 is a detail showing the overlap region and retaining element;

FIG. 7 is a detail showing the transition between the construction elements in the horizontal direction;

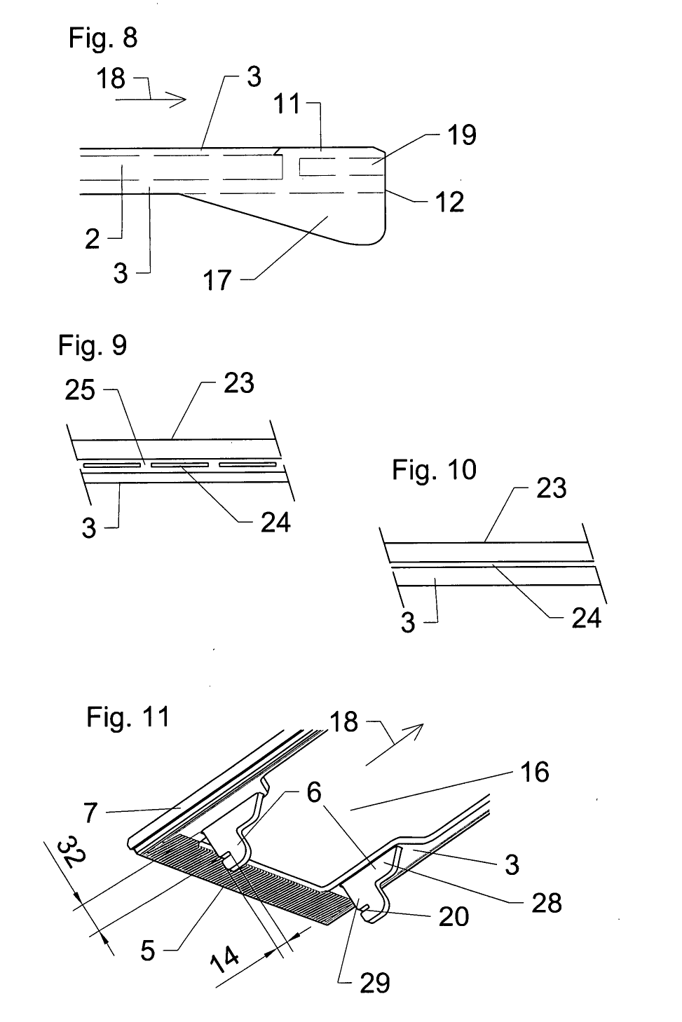

FIG. 8 is a detail showing the top part of the construction element with an electric terminal;

FIG. 9 is a detail showing an example of a rear-face, waterproof encapsulation of photovoltaic elements by means of the frame in the situation where the photovoltaic elements are additionally embedded with a material that is not waterproof;

FIG. 10 is a detail showing an example of a rear-face, waterproof encapsulation of photovoltaic elements by means of the frame where the photovoltaic elements are not embedded;

FIG. 11 is a perspective view from underneath showing a construction element with a different embodiment of the retaining elements.

FIG. 1 is a perspective view illustrating a device with flat, panel-shaped construction elements 1, of the type known from publication EP 1 362 967 A1 mentioned above. Rows of adjacent, flat, panel-shaped construction elements 1 arranged overlapping with one another in a scale pattern form a covering for a roof or a facade. Every construction element 1 is secured by two retaining elements 6 in the form of hooks on a roof batten serving as a support element 27, but the retaining elements 6 are not fixedly disposed on the construction elements 1. The retaining elements 6 extend through the overlap region 15 between the construction elements 1 and secure the construction element lying at the top by means of its bottom edge. The disadvantage of this is that in order to fit the construction elements 1, it is necessary both to lay profiled sections 26 to seal the construction elements in the horizontal direction and the retaining elements have to be fitted on the roof battens serving as support elements 27 beforehand.

FIG. 2 of the drawings is a perspective view from above showing a detail of a roof covered by means of the construction elements 1 proposed by the invention. The construction elements 1 may contain photovoltaic elements. The construction elements 1 overlap with one another in the vertical direction and are therefore disposed in rows in a scale pattern. The construction elements 1 are retained by means of retaining elements 6 (FIGS. 4 to 6) integrated in essentially horizontally disposed support elements 27. The latter are disposed on a conventional sub-structure 4. In the horizontal direction, the construction elements 1 are designed and disposed so that the structures of the frames 3 of two mutually adjacent construction elements 1 locate in one another and thus form a seal, as will be described in more detail below with reference to FIG. 7. Said frame 3 will be described in more detail with reference to FIGS. 4, 6 and 7.

FIG. 3 is a perspective view of the external face 23 of the construction element 1, in other words the side facing away from the building when the construction element 1 is in the fitted state, and FIG. 4 is a perspective view showing the internal face 16 of the construction element 1. In this particular embodiment, the panel part 2 of the construction element 1 has a frame 3 of plastic injected onto it by means of an injection moulding process. This frame 3 surrounds the panel part 2 at its edges and at some points also covers its internal and external face. In some applications, the frame 3 may also cover the entire internal face 16 of the panel part 2, e.g. in a situation in which the panel part 2 is provided with an non-encapsulated photovoltaic element on the internal face. The frame 3 may also contain a fire-retardant, flat element 22 such as steel wire or glass fibre netting, for example, so that parts of the construction element 1, in particular of the panel part 2, are pre-vented from falling if the panel part 2 breaks in the event of the building catching fire. Arrow 18 indicates the upward direction when the construction elements 1 are laid.

In the embodiment illustrated, two retaining elements 6 are connected to the construction element land its frame 3. They could also be mounted directly on the internal face of the panel part 2 of the construction element 1. Depending on the shape and size of the construction element 1, it would naturally be possible to provide only a single retaining element 6 or also more than two retaining elements 6. As illustrated here, these retaining elements 6 may comprise a part moulded on separately (FIG. 11) or a part secured to the construction element in some other way, totally injection moulded or a combination of these. They are positioned in the bottom half of the fitted construction element 1, on its internal face 16. At the very top on the internal face are bearings 17, by means of which the fitted construction element 1 sits on a support element 27 (FIG. 5), which may be a profiled rail, for example, as will be explained below with reference to FIG. 6. Integrated at the right-hand edge 7 and at the left-hand 8 edge are means to provide a seal with respect to the next adjoining construction element, which are illustrated in more detail in FIG. 7.

The frame 3 illustrated in FIG. 4 surrounds the panel part 2 at its edges on all four sides. In the situation where the panel part 2 is designed as a photovoltaic element or contains one, the edge of this panel part 2 is therefore also protected against ingress by moisture by means of this frame 3, in addition to any sealing means which might be provided. In the embodiment illustrated as an example here, however, care has been taken to ensure that the frame 3 does not project out beyond the plane of the external face 23 of the panel-shaped construction element at the bottom edge 5 of the construction element 1 so that water is able to drain away freely and dirt is not able to accumulate (see FIG. 6).

FIG. 5 is a side view showing the disposition of the construction elements 1 on a roof. A sub-structure 4 is provided with essentially horizontally extending support elements 27, on which the construction elements 1 lie directly and are secured by means of the retaining elements 6. A more detailed explanation of the design of the support elements 27 will be given in connection with FIG. 6. The construction elements 1 are laid in a scale-type pattern so that the bottom edge 5 of a construction element 1 overlaps with the top front face 12 of the adjacent construction element 1.

FIG. 6 illustrates the overlap region denoted by 15 illustrated in FIG. 5 but on a larger scale than in FIG. 5. The sub-structure 4 may comprise conventional roof spars or counter-battens, on which the support elements 27 are essentially horizontally disposed and secured. In the case of a facade covering (not illustrated), the sub-structure 4 may be provided in the form of counter-battens, for example. As clearly illustrated in FIG. 6, the support elements 27 in this example are provided as profiled rails with a double-T profile. Instead of a double-T profile, the support element 27 could also be of a different cross-section, for example a U-shaped cross-section. The only important thing is that the support element 27 should have free legs 21 directed upwards in the direction indicated by arrow 18, on which the retaining element 6 can locate in the manner described below and which is sufficiently wide for the adjacent construction element 1 underneath to lay against it by means of its bearings 17. Every retaining element 6 is disposed on the construction element 1 by means of a base part 28. The base part 28 may be connected to the frame 3, as illustrated in FIG. 4 for example, in which case the entire retaining element is preferably formed as an integral part of the frame 3. Adjoining the base part, the retaining element 6 has a spacer element 29 and on its end a slot 20. By means of this slot 20, the retaining element 6 surrounds said legs 21 of the support element 27 and holds the construction element 1 at a distance 32 from the support element. This being the case, the distance 32 is dimensioned so that there is room for the adjacent construction element 1 underneath to fit with its top edge 11 between the leg 21 of the support element 27 and the bottom edge 5 of the construction element 1. The support element does not therefore have to be stepped, as is the case with the known devices outlined above, and in the simplest case may be provided in the form of a flat section. If the support element 27 is provided in the form of a double-T section as in the example illustrated, another advantage is achieved due to the fact that when the sub-structure 4 is being built, allowance does not have to be made for the horizontal distance of the elements forming the sub-structure, for example spars or counter-battens, because the leg 21 is disposed at a distance from the sub-structure 4 and the sub-structure 4 and the retaining elements 6 on the support element 27 can not interfere with one another transversely.

As may also be seen from FIG. 6, the top front face 12 of every construction element 1 is spaced at a distance 13 apart from the slot 20 of the retaining element 6 of the adjacent construction element 1 above, and this distance 13 is bigger than the depth 14 of the slot 20 of the retaining element 6. As a result, every construction element 1 fitted in this manner can be removed and replaced at any time without having to remove adjacent construction elements 1 completely. This might be necessary for repair purposes or if a roof or a facade has to be extended. In order to remove it, the construction element 1 is pushed upwards (arrow 18) so far that the slots 20 of its retaining element 6 are no longer suspended on the leg 21 of the support element 27. Another advantage of this construction design is that when the construction elements 1 are being initially fitted, they can be laid in their sequence both from the top down and from the bottom up in the direction indicated by arrow 18.

The region of the construction element 1 and its frame 3 which lies in the overlap region 15 between two construction elements 1 lying at the top and bottom is roughened or provided with ridges, as indicated in FIG. 6. This prevents any rain water which there might be from penetrating any gap, however small, left by inaccuracies in the building and production techniques due to capillary action. The special design nevertheless allows any condensation water which might have accumulated on the internal face of the construction element 1 to drain away. The bearings 17 mentioned above in connection with FIG. 4 ensure good back-venting of the construction element 1 and permit a simple connection to conventional building materials, such as connecting plates, due to the distance of the construction element from the support element 27 and from the sub-structure 4. The bearings 17 also bring the construction element to the same thickness and position them in the same plane as conventional roof tiles.

FIG. 7 is a cross-section showing a detail of two mutually adjacent construction elements 9 and 10. As may be seen from the drawing, downwardly directed longitudinal ribs 30 are provided on the left-hand edge 8 of the construction element 9 disposed on the right-hand side longitudinal and other upwardly directed longitudinal ribs 31 are disposed on the right-hand edge 7 of the construction element 10 disposed on the right-hand side. These longitudinal ribs 30, 31 locate in one another and form a labyrinth seal.

The embodiment described as an example above generally relates predominantly to flat, panel-shaped construction elements 1. By particular preference, the panel parts 2 of these construction elements 1 may contain photovoltaic construction elements or be designed as such. These construction elements 1 can be fitted on appropriate sub-structures without additional fixing parts, preferably on back-vented sub-structures, in order to improve the efficiency of the photovoltaic elements by producing the lowest possible temperatures. In addition to generating electricity, such construction elements fulfil the function of a weather-resistant roof or facade skin, in the same way as roof tiles, slates, fibre-reinforced cement panels, ceramic panels, etc. The described construction elements 1 proposed by the invention may also be used with a range of different photovoltaic elements. Examples of these are mono-crystalline, polycrystalline, as well as thin-layer solar cells (amorphous, nano-crystalline, micro-crystalline, CIS etc.) of various designs, sizes and colours.

The construction elements proposed by the invention also permit the use of different designs of photovoltaic modules as elements, such as transparent and opaque glass/film laminates, glass/glass laminates and photovoltaic elements made from cast resin, for example. Construction elements may also be used which contain standard glass panels and blanking panels etc., for example to make chimney vents, roof-lights, framing for venting ducts or for laying in areas predominantly in the shade.

These photovoltaic construction elements 1 are simple, quick and thus inexpensive to fit. Since no unusual sub-structure is necessary, i.e. essentially only profiled rails 27 are mounted on a conventional sub-structure 4, fitting can be done by specialists trained in conventional roofing and facade building. The photovoltaic construction elements are merely suspended in the profiled rail 27 by means of the integrated retaining elements 6.

The electric circuitry of the individual photovoltaic construction elements 1 proposed by the invention is preferably connected during fitting when the relevant construction element has already been secured in its intended position on the sub-structure. Since electric voltage is already present at its electric terminals, this will require a connection system with contact- and polarisation-protected terminals, so that this work can be carried out by the above-mentioned specialists. The necessary electric bus lines, main lines, earth wiring, etc., is usually undertaken by specialist electricians.

In addition to the fact that the construction elements 1 proposed by the invention are compatible with conventional building cladding materials as mentioned above, the requisite sub-structure is also compatible with conventional sub-structures, which means that the construction elements 1 proposed by the invention may be fitted in conjunction with any other roofing and facade claddings, such as roof tiles, slates, fibre-reinforced cement panels, ceramic panels, etc., either in combination or subsequently.

FIG. 8 illustrates a detail of the top part of the construction element 1 with a schematically illustrated electric terminal 19 on the front face 12 of the construction element 1 disposed at the top in the fitted state. In the case of most known solar roof elements, the electric terminals are disposed on the rear face, which makes connection awkward because the connection has to be made before laying the construction element, which is not yet secured. The positioning of the terminals 19 illustrated here, in the plane of the construction element 1, avoids this problem. The electrical connection of this construction element 1 takes place immediately after laying, and, as mentioned above, the construction elements are advantageously laid from the bottom up.

FIG. 9 is a detail showing a construction element with a rear-face, waterproof encapsulation of photovoltaic elements 24 by means of the frame 3. The photovoltaic elements 24 are additionally embedded with a material 25 that is not sufficiently waterproof to protect against the weather, such as EVA (Ethyl Vinyl Acetate) for example.

FIG. 10 shows a detail similar to that of FIG. 9, with an example of a rear-face waterproof encapsulation of photovoltaic elements 24 by means of the frame 3 in the situation where there is no additional embedding of the photovoltaic elements 24.

If the panel part 2 is designed as a photovoltaic element or contains one as described above, it is of particular advantage if, as illustrated in FIG. 6, the frame 3 is wide enough at the top edge 11 of the construction element for the bottom edge 5 of the adjacent construction elements 1 above not to extend over the photovoltaic element.

FIG. 11 is a perspective view from underneath illustrating a construction element with a different embodiment of the retaining elements. As illustrated, the base part 28 and the spacer element 29 of each retaining element 6 in this instance is of the same width and formed integrally with the frame 3 of the construction element. This being the case, the slots 20 may be formed during manufacture of the frame 3 or may be formed subsequently by milling.

### LIST OF REFERENCE NUMBERS

1 Construction element
2 Panel part of 1
3 Frame of 1
4 Sub-structure, e.g. counter-battens
5 Bottom edge of the construction element
6 Retaining element
7 Right-hand edge of 10
8 Left-hand edge of 9
9 Right-hand construction element
10 Left-hand construction element
11 Top edge of 1
12 Top front face
13 Distance between 12 and 6 or 20
14 Slot depth
15 Overlap region
16 Internal face of the construction element
17 Bearing of 1 at the top edge
18 Upward direction in the plane of the panel-shaped construction element
19 Electric terminal point
20 Slot
21 Leg of 27
22 Element of flame-retardant material
23 External face of the construction element
24 Photovoltaic elements
25 Generally non-waterproof material embedding the photovoltaic elements
26 Water-draining profiled rails
27 Support element
28 Base part of 6
29 Spacer element of 6
30 Longitudinal ribs on 8
31 Longitudinal ribs on 7
32 Distance between 27 and 3

1. Roof or facade cladding comprising panel-shaped construction elements (1) disposed in a scale-type pattern, and each construction element (1) has at least one retaining element (6) disposed on the internal face (16) of the construction element (1) directed towards the building, and each construction element (1) is secured by the at least one retaining element (6) on an essentially horizontally disposed support element (27) whereby a slot (20) provided in the retaining element (6) opening at the bottom extends round the support element (27) in a clamping arrangement, and the at least one retaining element (6) is disposed on the construction element (1) adjacent to the bottom, essentially horizontally oriented edge (5) of the construction elements (1) and the slot (20) of the retaining element (6) extending round the support element (27) lies closer to this bottom edge (5) than the top front face (12) of the construction element (1), wherein the construction element (1) comprises at least a panel part (2) and a frame (3) at least partially surrounding the panel part (2) and the distance of the slot (20) from the internal face (16) of the construction element corresponds to at least the thickness of the construction element (1) at its top front face (12).

2. Roof or facade cladding as claimed in claim 1, wherein the retaining element (6) is disposed on the frame (3).

3. Roof or facade cladding as claimed in claim 2, wherein the retaining element (6) is integrally joined to the frame (3).

4. Roof or facade cladding as claimed in claim 1, wherein the frame (3) is made from plastic and is preferably manufactured by an injection moulding process.

5. Roof or facade cladding as claimed in claim 4, wherein the panel part (2) is joined to the frame (3) by injecting it round the panel part (2).

6. Roof or facade cladding as claimed in claim 1, wherein the support element (27) is provided in the form of a profiled bar secured to a sub-structure (4), which has upwardly pointing (arrow 18) legs (21) spaced at a distance apart from the sub-structure (4).

7. Roof or facade cladding as claimed in claim 1, wherein in the overlap region of the bottom edge (5) of the construction element (1), the face directed towards the support element (27) and/or the top edge (11) of the construction element (1) on the face directed away from the support element (27) is roughened or provided with ridges and/or ribs.

8. Roof or facade cladding as claimed in claim 1, wherein the side edges (7, 8) of every construction element (1) are provided with elements (30, 31) which locate in a sealing engagement with co-operating elements (31, 30) of the horizontally adjacent construction element.

9. Roof or facade cladding as claimed in claim 1, wherein the frame (3) at the bottom edge (5) does not project beyond the panel part (2) perpendicular to the plane of the panel part (2).

10. Roof or facade cladding as claimed in claim 1, wherein the construction element (1) contains a flat element (22) of inflammable material on its rear face.

11. Roof or facade cladding as claimed in claim 1, wherein at least a part of the panel part (2) is designed as a photovoltaic element or contains one.

12. Roof or facade cladding as claimed in claim 11, wherein the frame (3) at the top edge (11) of the construction element (1) is sufficiently wide and the distance between the support elements (27) such that the bottom edge (5) of the adjacent construction element (1) above does not extend across the photovoltaic element or does so only by a maximum of 5% of the vertical length of the photovoltaic element.

13. Roof or facade cladding as claimed in claim 11, wherein at least one electric terminal point (19) is provided in the top edge (11) of the construction element, which is preferably accessible from the front face (12) of the top edge (11).

14. Roof or facade cladding as claimed in claim 11, wherein the photovoltaic elements are disposed on the internal face of the panel part (2) and the frame (3) is designed so that it forms the waterproof encapsulation of the photovoltaic elements, and the external face of the panel part (2) is waterproof.
